(19) United States
(12) Patent Application Publication
(10) Pub. No.: US 2022/0113632 A1
(43) Pub. Date: Apr. 14, 2022

(54) GAUGE SELECTION FOR MODEL CALIBRATION

(71) Applicant: ASML NETHERLANDS B.V., Veldhoven (NL)

(72) Inventors: Lei WANG, Los Gatos, CA (US); Mu FENG, San Jose, CA (US); Qian ZHAO, San Jose, CA (US)

(73) Assignee: ASML NETHERLANDS B.V., Veldhoven (NL)

(21) Appl. No.: 17/431,226

(22) PCT Filed: Feb. 7, 2020
(86) PCT No.: PCT/EP2020/053204

§ 371 Date: Aug. 16, 2021

Related U.S. Application Data
(60) Provisional application No. 62/811,281, filed on Feb. 27, 2019.

(51) Int. Cl. G03F 7/20; H01L 21/66

(52) U.S. Cl. CPC G03F 7/705; H01L 22/20; H01L 22/12; G03F 7/70625

(57) ABSTRACT

A method for gauge selection for use in calibrating a process model associated with a patterning process. The method involves obtaining a set of initial gauges having one or more properties (e.g., gauge name, weight, dose, focus, model error, etc.) associated with the patterning process; and selecting a subset of initial gauges from the set of initial gauges, the selecting the subset of initial gauges including determining a first subset of gauges from the set of initial gauges based on a first property parameter of the one or more properties, the first subset of gauges being configured to calibrate a process model (e.g., optics model, resist mode., etc.).

### CROSS-REFERENCE TO RELATED APPLICATIONS

This application claims priority of U.S. application 62/811,281 which was filed on Feb. 27, 2019 and which is incorporated herein in its entirety by reference.

### TECHNICAL FIELD

The description herein relates generally to test patterns for model calibration associated with a lithography process, and more specifically to selecting an optimal set of test patterns from a larger set of test patterns.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involve processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-kl lithography, according to the resolution formula CD=k1λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

OPC and other RET utilize robust models that describe the lithography process precisely. Calibration procedures for such lithography models are thus desired that provide models being valid, robust and accurate across the process window. Currently, calibration is done using a certain number of 1-dimensional and/or 2-dimensional gauge patterns with wafer measurements. More specifically, those 1-dimensional gauge patterns include, but are not limited to, line-space patterns with varying pitch and CD, isolated lines, multiple lines, etc. and the 2-dimensional gauge patterns typically include line-ends, contacts, and randomly selected SRAM (Static Random Access Memory) patterns.

The term “projection optics,” as used herein, should be broadly interpreted as encompassing various types of optical systems, including refractive optics, reflective optics, apertures and catadioptric optics, for example The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

The present invention provides a number of improvements in the area of test pattern selection for model calibration that address the lithography related requirements (e.g., feature size, OPC related, etc.) mentioned above, among others. An advantage of the present invention is that it provides an improved way to measure characteristics of a given test pattern, and at the same time, provides an efficient way to select a subset of test patterns that adequately represent intended lithographic responses. The terms “calibration test pattern”, “test pattern” and “gauge” are used interchangeably.

A method for improving a gauge selection to calibrate a process model for a patterning process includes obtaining a set of initial gauges having one or more properties associated with the patterning process. The method also includes selecting a subset of initial gauges from the set of initial gauges. The one or more properties may include a value of critical dimension of a wafer, a curvature associated with the pattern; and/or an intensity used in the patterning process.

In some variations, the first property parameter may include a model error, and the model error is a difference between a reference contour and a simulated contour generated from a simulation of a process model of the patterning process, and the reference contour is a measured contour from a scanning electron microscope.

The method also includes determining a first subset of gauges from the set of initial gauges based on a first property of the one or more properties, and the first subset of gauges can be configured to calibrate a process model.

In some variations, the method also includes the set of the initial gauges is filtered by use of user defined gauges to determine the first subset of gauges.

In other variations, a second subset of gauges is determined from the set of initial gauges based on a second property of the one or more properties. The method also includes the first subset of gauges and the second subset of gauges being merged to be a merged subset of gauges. After merging the first subset of gauges and the second subset of gauges, the method further includes determining whether the merged subset of gauges include duplicate gauges.

The method further includes a third subset of gauges is selected from the merged subset of gauges such that the third subset does not include the duplicate gauges, and the third subset of gauges is configured to calibrate a process model.

In some variations, the merged subset of gauges is selected to calibrate the process model in response to the determination that no duplicate gauges exist.

In other variations, initial gauges having one or more properties associated with the patterning process are obtained.

In some variations, a plurality of models is calibrated by an optimization algorithm using the initial gauges, and the plurality of models are configured to determine gauges. Each model of the plurality of models is associated with a model error value.

In other variations, candidate models from the plurality of models based on a comparison of the model error value with respect to a lowest model error value of a particular model in the plurality of models are determined. The gauges for the patterning process based on the candidate models are then selected.

In some variations, a cosine similarity metric between each of the candidate models is determined, and the cosine similarity metric is a cosine of two vectors, each vector being representative of a given model of the candidate models.

In other variations, a user-defined number of diverse models from the candidate models is selected based on the similarity metric, and the diverse model has a value of the similarity metric substantially different from a value of the similarly metric of a model having lest model error value.

In some variations, the model error value is associated with a model error, and the model error is a difference between a reference contour and a simulated contour generated from a simulation of a process model of the patterning process. The reference contour can be a measured contour from an image capture device. The model error value can be a root mean square value of the difference between the reference contour and the simulated contour.

According to an embodiment, there is provided a computer program product comprising a non-transitory computer readable medium having instructions recorded thereon. The instructions, when executed by a computer, implement the methods listed in the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 illustrates a flowchart of an exemplary method of improving gauge selections by initial gauge selection and model error based selection, according to an embodiment.

FIG. 4 illustrates a flowchart of an exemplary method of selecting initial gauges, according to an embodiment.

FIG. 5 illustrates a flowchart of an exemplary method of selecting gauges based on one or more properties, according to an embodiment.

FIG. 6 illustrates a flowchart of an exemplary method of fast genetic algorithm gauge selection, according to an embodiment.

FIG. 7 illustrates a flowchart of an exemplary method of model selection, according to an embodiment.

FIG. 8 illustrates a flowchart of an exemplary method for improving gauge selection based on the selected model of FIG. 7, according to an embodiment.

FIG. 9A illustrates an exemplary method of gauge selection for use in calibrating a process model associated with a patterning process, according to an embodiment.

FIG. 9B illustrates an exemplary method of selecting a subset of initial gauges, according to an embodiment.

FIG. 10A illustrates an exemplary method of generating gauges for a patterning process, according to an embodiment.

FIG. 10B illustrates an exemplary process of obtaining initial gauges of FIG. 10A, according to an embodiment.

FIG. 10C illustrates an exemplary method of determining a cosine similarity metric between each of the candidate models of FIG. 10A, according to an embodiment.

FIG. 11 illustrates an exemplary of gauge data in a table form (an example of a dataframe), according to an embodiment.

FIG. 12 illustrates representation of the plurality of models (e.g., in method of FIG. 10A-10C), according to an embodiment.

FIG. 13 illustrates an example of similarity of different models, according to an embodiment.

FIG. 14 is a block diagram of an example computer system, according to an embodiment.

FIG. 15 is a schematic diagram of a lithographic projection apparatus, according to an embodiment.

FIG. 16 is a schematic diagram of another lithographic projection apparatus, according to an embodiment.

FIG. 17 is a detailed view of the lithographic projection apparatus, according to an embodiment.

FIG. 18 is a detailed view of the source collector module of the lithographic projection apparatus, according to an embodiment.

FIG. 19 schematically depicts an embodiment of an electron beam inspection apparatus, according to an embodiment.

FIG. 20 schematically illustrates a further embodiment of an inspection apparatus, according to an embodiment.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.

An example of a programmable LCD array is given in U.S. Pat. No. 5,229,872, which is incorporated herein by reference.

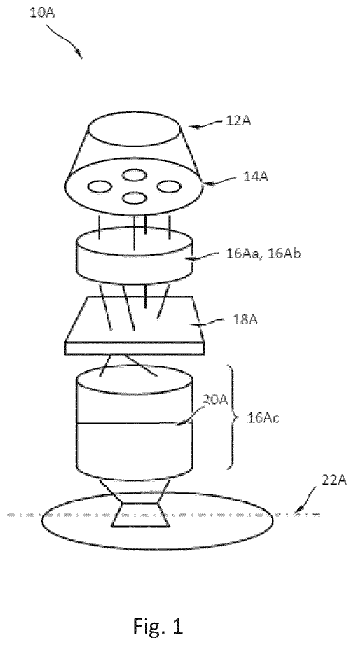

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

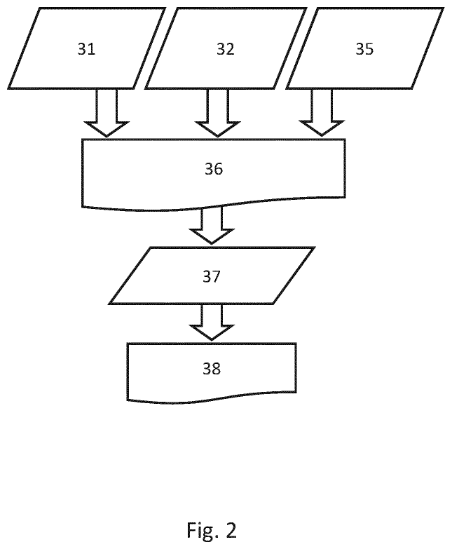

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

CF(z₁, z₂, . . . , z_{N})=Σₚ₌₁^{p} wₚfₚ²(z₁, z₂, . . . , z_{N}) (Eq. 1)

where (z₁, z₂, . . . , z_{N}) are N design variables or values thereof. fₚ (z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ (z₁, z₂, . . . , z_{N}). For example, the characteristic may be a position of an edge of a pattern, measured at a given point on the edge. Different fₚ (z₁, z₂, . . . , z_{N}) may have different weight wₚ. For example, if a particular edge has a narrow range of permitted positions, the weight wₚ for the fₚ (z₁, z₂, . . . , z_{N}) representing the difference between the actual position and the intended position of the edge may be given a higher value. fₚ (z₁, z₂, . . . , z_{N}) can also be a function of an interlayer characteristic, which is in turn a function of the design variables (z₁, z₂, . . . , z_{N}). Of course, CF (zᵢ, z₂, . . . , z_{N}) is not limited to the form in Eq. 1. CF (zᵢ, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ (z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N}) ∈ Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “target pattern” means an idealized pattern that is to be etched on a substrate.

As used herein, the term “printed pattern” means the physical pattern on a substrate that was etched based on a target pattern. The printed pattern can include, for example, troughs, channels, depressions, edges, or other two and three dimensional features resulting from a lithography process.

As used herein, the term “process model” means a model that includes one or more models that simulate a patterning process. For example, a process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and an OPC model (e.g., that can be used to make target patterns and may include sub-resolution resist features (SRAFs), etc.).

As used herein, the term “calibrating” means to modify (e.g., improve or tune) and/or validate something, such as the process model.

The present disclosure describes, among other things, methods for improving a process model for a patterning process. Improving metrology during process model calibration can include obtaining accurate images of a printed pattern (e.g., a printed wafer or portion thereof) that is based on a target pattern. From the images, contours can be extracted that correspond to features on the printed pattern. The contours (also referred to as measured contours) can then be aligned to simulated contours, generated by the process model, to allow for calibration of the process model. The process model can be improved by adjusting parameters in the process model such that the simulated contours more accurately match the measured contours.

The present disclosure is generic enough to accommodate any type of pattern. These patterns are then imaged onto a wafer and resulting wafer CDs and/or contact energy are measured. The original gauge patterns and their wafer measurements are then used jointly to determine the process model parameters (e.g., related to dose and focus) which minimize the difference between model predictions and wafer measurements.

In current practice, the selection of gauge patterns is rather arbitrary. They may simply be chosen from experience or randomly chosen from the real circuit patterns. Such patterns are often insufficient for calibration or too computationally-intensive due to redundancy. In particular, for some model parameters (e.g., related to dose and focus, other parameters related to optics model, resist model, etc.), all the patterns may be quite insensitive thus it may be difficult to determine the model parameter values due to measurement inaccuracies. While on the other hand, many patterns may have very similar responses to parameter variations (also called process conditions) thus some of them are redundant and wafer measurements on these redundant patterns waste a lot of resources.

Meanwhile, process models need to accurately predict the actual on-wafer pattern contours across a very large collection of possible geometric layout patterns. Therefore, both the proper choice of the model formulation to be employed and the accurate determination of values for all model parameters is desirable.

Moreover, in the calibration of a process model, wafer CD measurements for the selected test patterns are needed to optimize the model parameters. Collecting such metrology data is often time-consuming and expensive. In light of this effort, these calibrations (e.g., models in the OPC application) are typically done only once per technology node per target layer. For computational lithography products (which employ calibrated process models) in manufacturing, these calibrations need to be done for many scanners and on a somewhat regular basis. Therefore, model calibration procedures should address the issue of how to minimize the number of test structures that need to be measured without compromising the prediction accuracy of the resulting model.

Traditional approaches in model calibration aim primarily to provide a good description of the imaging behavior of those patterns that are known to be desirable in the physical circuit design community. Typically, this involves a substantial number of pattern types, each instantiated over an appropriate range of geometric variations. One example is line CD versus pitch for the poly layer, for a number of frequently used transistor channel lengths (poly line CD) and from dense lines (minimum pitch) to isolated lines. However, in modern lithography, the optical range of influence (ambit) is much larger than the typical test structure and therefore it is no longer true that accurate modeling of a pre-selected number of relatively small test patterns guarantees accurate prediction of these patterns in their actual circuit environments. Most of the geometry-based approaches are somewhat heuristic in nature, and are often prone to one or all of the following drawbacks.

Firstly, the strong focus on predefined patterns means that there is no explicit consideration for proper coverage of model parameters and for guaranteeing that all the significant physical/chemical characteristics in a lithography process are suitably represented by these parameters. In the case of a model not based on first principle physics/chemistry, the predefined patterns similarly need to allow accurate calibration of the model's parameters. Due to a lack of discriminating patterns, patterns can be poorly determined or they can exhibit a high degree of degeneracy with other parameters. Either way, the methods routinely fail to properly describe the change in imaging behavior outside the conditions included in the model characterization.

Secondly, for some of the physical/chemical properties and associated model parameters that are captured by the calibration method, the approach is not economical and too many measurements provide essentially redundant information.

Thirdly, the current gauge selection methods are not easily generalizable. Every time a new gauge geometry is supplied, the user needs to establish new rules. If a gauge selection is done using a purely non-geometry-based approach, then specific features of a given gauge are ignored. The increased use of computational lithography models outside their original conventional application, e.g., in OPC implies that the model calibration procedures need to be adjusted also, such that the resulting models are at least: a) better in predicting imaging behavior for pattern types not included in the calibration test data, b) better in predicting imaging behavior for variations in the lithographic processing conditions (mask, scanner, resist, or etch related), and c) more frugal in terms of the amount of metrology needed. Accordingly, a need exists to address one or more of the shortfalls of the traditional methods. Example gauge selection process to improve model calibration is described U.S. Pat. No. 9,588,439 incorporated herein by reference in its entirety.

In an existing approach, a gauge selection is based on focus-exposure (FEM) matrix. In this method, signal analysis of a full gauge set is used for pattern grouping and one representative gauge is selected. However, current method cannot guarantee that the selected gauges include a model error limiter. For example, certain models may cause relatively higher model error for particular gauge than other gauges such as selected at nominal process conditions. Thus, gauge selection process aware of model errors is proposed in the present disclosure.

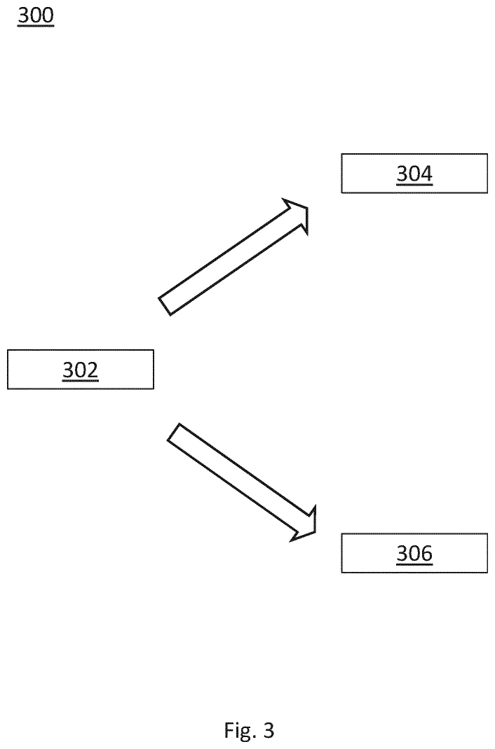

In the present disclosure, FIG. 3 illustrates a flowchart of an exemplary method of improving gauge selections by initial gauge selection and model error based gauge selection, according to an embodiment.

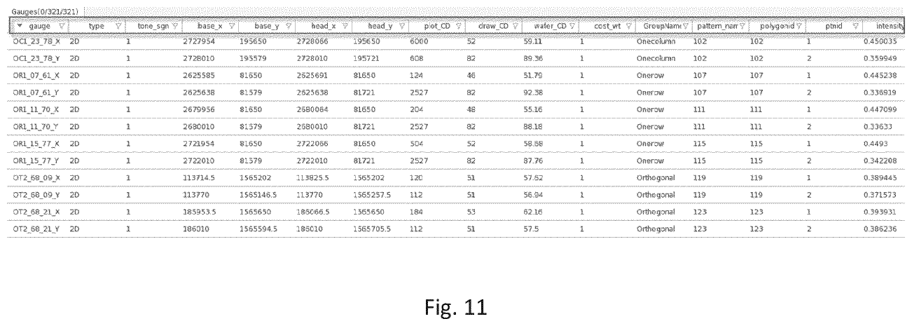

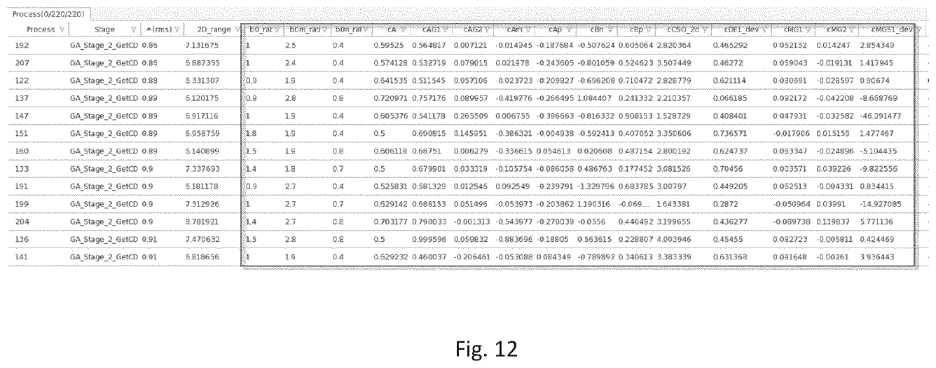

In one embodiment, as illustrated in FIG. 3, the present disclosure provides a workflow of an example method 300 of a gauge selection module. The method comprises as an initial step 302, selecting a set of initial gauges having one or more properties associated with the patterning process from a full-gauge set (e.g., comprising more than 1 million gauges) available. In an embodiment, a property can a gauge name associated with a process model, a value of critical dimension of a wafer; a curvature associated with the pattern; an intensity used in the patterning process, or other patterning related process parameters. An example of properties is listed in FIG. 11, discussed later in the disclosure.

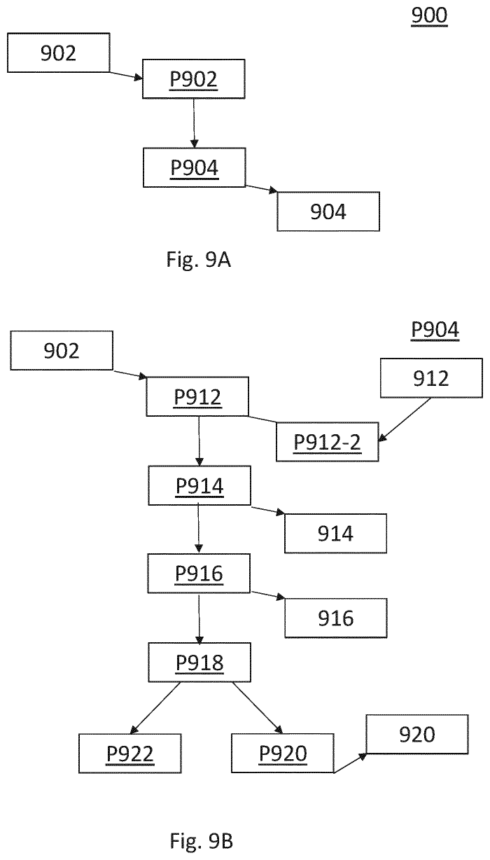

The initial selecting step 302 can be accomplished in a number of methods, e.g., further discussed with respect to FIG. 9A and 9B. In an embodiment, a set of input gauges (e.g., 902 in FIG. 9A) having one or more properties (e.g., property1, property 2, property 3, etc. in FIG. 11) associated with the patterning process is obtained. In embodiment, the input gauges may be a full-gauge set (e.g., having more than 1 million gauges) and the after performing the initial selection process 302, a subset of input gauge is obtained. This subset is referred as an initial gauges. In an embodiment, gauges and related data including properties associated therewith may be stored in a file in a memory of a computer or server. In an embodiment, a user interface may be provided to enable a user to retrieve a stored list of such gauges. In an embodiment, the number of gauges in the input gauges may be very high e.g., more than 1 million. As mentioned earlier, high number of gauges may be undesired as it affects reduces a throughput of the patterning process, increases metrology time and effort, redundant measurements may be taken, etc.

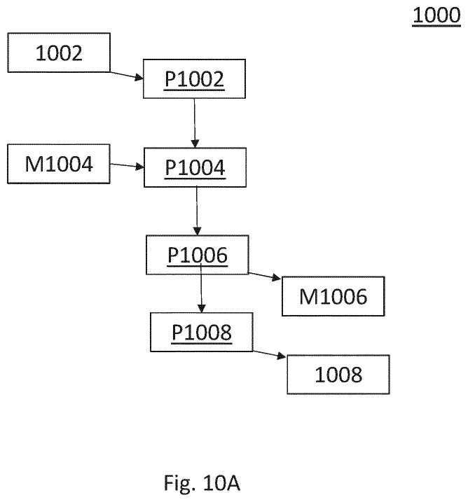

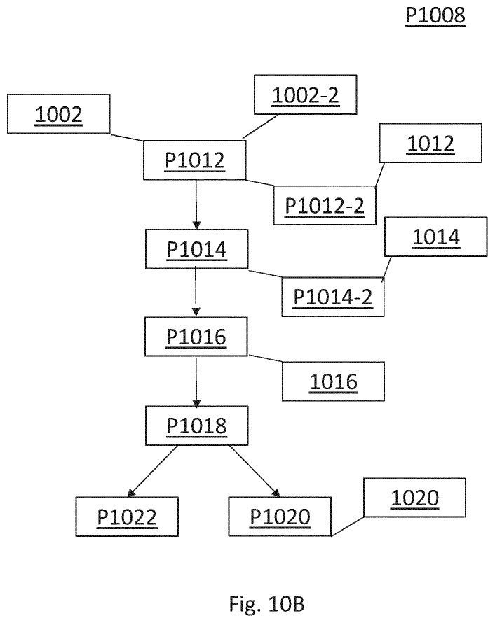

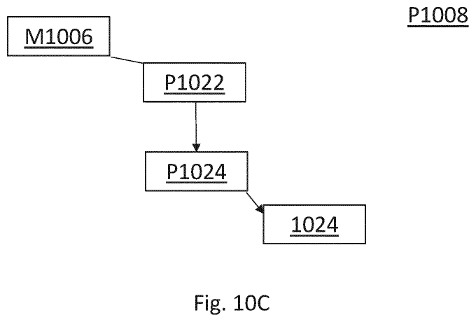

In an embodiment, the input gauges are considered to be gauges that are initially gathered and that will be reduced (e.g., according to method in FIG. 9A-9B and 10-10B). For example, the input gauges (e.g., 100,000; 500,000; 1 million, or more etc.) are reduced to a first subset of gauges (e.g., 10,000; 5000; 1000; or less) from the set of input gauges based on a first property parameter of the one or more properties, and the first subset of gauges is configured to calibrate a process model. In an embodiment, the property parameter refers to a gauge name, model error, or other properties or values thereof.

In an embodiment, the method may include additional inputs for the initial gauge selection. Data from these additional inputs may be used for filtering initial gauges. For example, the inputs and associated data may be: (i) a full gauge set data associated with a full-chip or an entire substrate previously printed via the patterning process, (ii) one or more property files associated with full gauge set, (iii) an initial gauge selection number, which defined a total number of gauges desired to be selected (e.g., less than 10,000), (iv) a user-defined gauge file comprising desired gauges and data (e.g., one or more properties, values of the properties, etc.) associated therewith that a user would like to keep regardless of obtained sub-set of gauges (e.g., a first subset), and/or (v) a path to a memory location of a computer to store the selected sub-set of gauges.

In an embodiment, the user-defined gauge file is also referred as user-kept gauges or desired gauges. Such user-kept data can be any gauges (e.g., associated with a particular pattern such as a test pattern, a relatively dense pattern used for OPC, a memory portion of a circuit, etc.). The user-kept gauges may be part of the full-gauge set. In an embodiment, upon applying the initial selection step 302, such user-kept gauges or desired gauges may be filtered out, hence option to include or append the selected-subset with the user-defined gauges is provided. In an embodiment, the user-kept gauge may be an empty set i.e., the user-kept gauge file may not include any data.

In an embodiment, the method may further include a step for model-based gauge selection, wherein additional properties such as model error may be determined and associated with a particular gauge. Such model error may be further used to generate or select a sub-set of initial gauges or gauges output from the step 302.

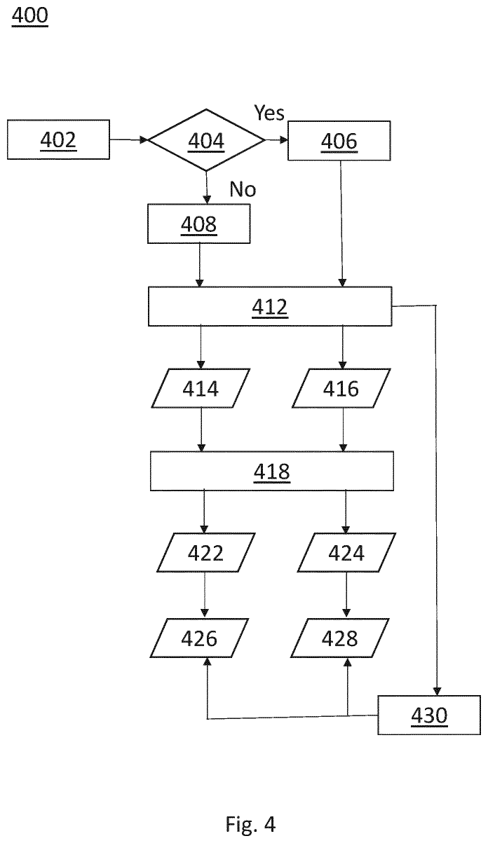

In an embodiment, the model-based gauge selection process 304 employs an optimization algorithm to generate process models. For example, the optimization algorithm may be a fast genetic algorithm. The genetic algorithm generates a plurality of models, each model having model parameters determined based on an optimization cost function such as a difference between a model result (e.g., a simulated contour) and a reference result (e.g., a desired contour). Based on the plurality of models, additional gauges may be generated as well. Such additional gauges may be used to append (i.e., added) to a first subset of gauges. The model-based selection process 304 is further discussed with respect to FIGS. 4,5, and 10A-10B.

In an embodiment, for step 304 (or 306), may receive additional inputs and associated data similar to that for step 302, discussed earlier. For example, the inputs may be (i)-(vi), as mentioned earlier; (vii) a root mean square, (viii) a model identifier (e.g., a model number) associated with a process model to be employed in gauge selection process, (ix) number of models (e.g., 15, 10, 5, or less.) to be selected, and/or (x) one or more de-noise parameters that eliminates any outlier determined based on model errors ranges or model error biases.

In an embodiment, the model error may be obtained via simulation of process models. For example, model error is a difference between a reference contour (or a desired contour) of a desired pattern and a simulated contour generated from the simulation of a process model of the patterning process (e.g., as discussed in FIG. 2). In an embodiment, the reference contour can be a measured contour of a printed pattern. The measured contour may be obtained via metrology tool such as a scanning electron microscope. In embodiment, root mean square refers to a method used to compute the model error, thereby the model error is referred as a root mean square error. In root mean square, a difference in mean value (e.g., mean CD value of pattern) associated with a model result and a model result (e.g., CD value predicted via executing the process model) is obtained, the difference is squared, and a square root of the squared difference is determined.

In one embodiment, the method may optionally include a step 306 for fine-tuning the models obtained via the genetic algorithm. The fine-tuning process typically involves modifying parameters of the genetic algorithm to obtain fine-tuned parameter values for the process models so that the model error is minimized It can be understood by a person skilled in the art that the present disclosure that the genetic algorithm or a fine-tuning process associated therewith is used as an example to explain the concepts of the present disclosure. Any other optimization method may be employed for the model-based selection process without limiting the scope of the present disclosure.

FIG. 4 illustrates more detailed steps of an exemplary method 400 of selecting initial gauges (e.g., step 302 of FIG. 3), according to an embodiment.

The method 400 can is used for gauge selection for use in calibrating a process model. In an embodiment, such calibrated model may be used to control parameters of the patterning process so that a performance metric (e.g., CD, EPE, yield, etc.) may be improved. In an embodiment, the gauges may also be used in a measuring process, via a metrology tool associated with a patterning process to measure appropriate gauges, thereby reducing metrology time, which can further improve the yield of the patterning process.

The method 400 comprises as an initial step 402 to start the initial selection process. In an embodiment, at the initial step 402, inputs such a full-gauge set comprising a user-kept gauges, reference gauges (also referred as reference data) or other user-inputs may be obtained, as discussed earlier in FIG. 3. At step 404, a determination is made whether a process model (e.g., optical model, resist model, etc. of FIG. 2) pre-exists in a memory (e.g., of a computer system). The model may be a calibrated model based on patterning process data obtained from a previously process substrate or printed substrates. If there exists a process model, then at step 406, a check is performed using the process model to identify a sub-set (e.g., 416) of initial gauges of 402.

In an embodiment, the checking at 406 may involve determining gauges associated with the process model, checking one or more properties of a gauge associated with the model, checking for model error values associated with input gauges of step 402, and/or generating, via model execution, properties (e.g., model error) for input gauges of step 402. The checking results, in subsequent steps, a sub-set of gauges (e.g., 416). In an embodiment, one or more such information related to the models or gauges may be stored in a database or memory of the computer system and retrieved according to one or more inputs of a gauge selection process mentioned earlier.

If a process model (e.g., optics model of FIG. 2) does not exist (e.g., in a database or memory), then, at step 408 reference gauges may be obtained or inputs of initial step 402 may be further used in gauge selection process. Thus, in an embodiment, a sub-set of gauges may be determined using the reference gauges. In an embodiment, the reference gauges may be obtained from (e.g., a database) a previously processed substrate data as mentioned earlier.

At step 412, a filtering of input gauges (e.g., input of 402 or outcome from 406) based on a user-kept gauges, as mentioned earlier, may be performed. For example, from the input gauges (e.g., input of 402 or output of 406), a sub-set of gauges 414 or 416 may be selected by removing the user-kept gauges from the input gauges. In an embodiment, sub-set 414 and 416 are also referred as filtered gauges 414 and 416, respectively. As mentioned earlier, there may be 1 million input gauges and these 1 million input gauges may include 1000 user-kept gauges. Then, after filtering, less than 999,000 filtered gauges remain. These are still very high number of gauges, thus further selection of sub-set of gauges is done in subsequent steps (e.g., at 418).

At step 418, a sub-set of gauges (e.g., 422 and/or 424) are selected from the filtered gauges 414 and/or 416 based on one or more properties associated with the filtered gauges. The one or more properties may be a first property parameter. For example, the first property is a gauge name associated with a desired gauge such as CD of 20 nm. Alternatively or in an addition, in an embodiment, the property parameter may be intensity value of a patterning process. Thus, based on one or more properties used for selection, a sub-set 422 (or 424) of input gauges (of 402 or 406) may be selected. For example, the selected sub-set may include less than 10,000 gauges. As mentioned earlier, the one or more properties used for selection of sub-set 422 or 424 may be a value of critical dimension of a wafer, a curvature associated with the pattern, model error (e.g., additional property added from step 406) and/or an intensity used in the patterning process.

In a subsequent step 430, the selected sub-set of gauges 422 and/or 424 may be further appended to include the user-kept gauges that were used at step 412 to output gauges 426 and/or 428, respectively. Such appending of the user-kept gauges are thereby preserved, such gauges were desired gauges or critical gauges. In an embodiment, the subset of gauges 422/424/426/428 may be interchangeably referred as selected gauges, selected sub-set of gauges, or input gauges when used with further model-based selection process as discussed in e.g., FIG. 10A-10B.

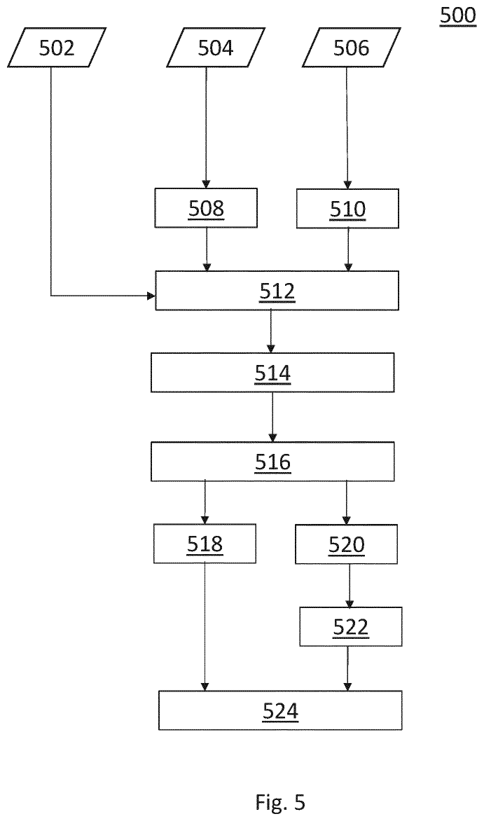

FIG. 5 is a flowchart of an example implementation of method 500 for selecting gauges based on one or more properties, e.g., at step 418 discussed in FIG. 4. In an embodiment, inputs may be provided to the method 500. A first input may be a number of gauges 502 (e.g., a user-defined or a pre-determined number) to be selected from an initial set of gauges (e.g., reference gauges or full-set of gauges). A second input 504 may be a gauge file 504 (e.g., stored in a memory of a computer system) comprising gauge data such as gauge name, properties of a gauge or patterning process, values of each of the properties, or other gauge related data. Example of gauge file and data within the file is illustrated in FIG. 11. A third input 506 may be a list of one or more properties to be used for selection purposes. In an embodiment, each of the one or more properties may be associated with a weight, which indicates an importance of a particular property. Initially, all the properties may be assigned an equal weight e.g., value 1. The one or more properties may include a value of critical dimension of a wafer, curvature associated with the pattern, and/or an intensity used in the patterning process, etc. as mentioned earlier.

At step 508, a dataframe 508 may be generated by using the gauge file 504. A dataframe is an example representation of data in a gauge file 504 (the second input). For example, the dataframe include rows and columns comprising properties and their values. In an embodiment, each row lists all a property related to a gauge, further each row being associated with a column. The column represents value of each of the listed property.

At step 510, another dataframe 510 may be generated by sorting data e.g., in the gauge file 504, based on one or more properties 506 (the third input). For example, the step 510 generates a sorted dataframe based on values of name or weight in the gauge file 504. In an embodiment, the one or more properties 506 may be a newly added property (e.g., model error) associated with a gauge, but such property (e.g., model error) does not previously exist in the gauge file 504. In an embodiment, the dataframe 510 and 508 may be used to selection purposes. In an embodiment, the dataframe 508 is an example of an initial set of gauges and the sorted dataframe 508 is an example of the one or more properties based on which selection of gauges is performed.

At step 512, the dataframes 510 and/or 508, and the number of gauges (e.g., 1000 gauges) to be selected 502 may be used for gauge selection. At the step 512, the selecting of the subset of gauges is based on the one or more properties, mentioned above. For example, a first sub-set may be selected from the dataframes 510 and 508 based on a first property parameter such as a gauge name. Additionally or alternatively, a second subset of gauges may be selected from the dataframes 510 and 508 based on a second property such as intensity. Additionally or alternatively, a third, a third subset of gauges may be selected from the dataframes 510 and 508 based on a third property such as curvature of a pattern. Additionally or alternatively, a fourth subset of gauges may be selected from the dataframes 510 and 508 based on a fourth property such as location (e.g., edge of a substrate, center of a substrate) of a gauge on the substrate.

Further, the first subset of gauges, the second subset of gauges, and so on may include duplicated gauges. For example, the first subset of gauges may include a gauge identified by a named OCI_23_78_X and the second subset of gauges may also include the gauge OCI_23_78_X. Such duplication may be redundant. Thus, in an embodiment, further unique gauges may be selected from the first subset, the second subset, and so on based on one or more properties such as gauge name (or model error, weight, etc.).

Hence, a merging step 514 may be included to identify duplicate gauges. At the merging step 514, the first subset of gauges, the second subset of gauges, and so on are merged to be generate a merged subset 514 of gauges. The merging of subset simply refers to appending the first subset with the second subset of gauges. In an embodiment, the merging may be ordered based on the importance of one or more property, where a sub-set associated with the most important property is positioned first, and a sub-set associated with a least important property is positioned last in the merged subset. As will be evident, the merged sub-set of gauges 514 including the duplicate gauges will have the first property, the second property, and so on.

Next, at step 516, it is determined whether the merged subset of gauges include the set of duplicate gauges (e.g., based on gauge names). The determination may be made by comparing gauges of different sub-sets, sorting based on one or more properties and then comparing the gauges listed adjacent to each other, or other known method of identifying duplicate entries in data. For example, the determining is accomplished by comparing the first subset of gauges and the second subset of gauges based on a first property (e.g., name).

Upon determining duplicate gauges are present, at step 520, the set of duplicate gauges may be filtered out from the merged subset of gauges 516. Removing of duplicate gauges may be desired to improve performance of calibration process, measurement process, etc. of the patterning process. When the selected sub-set of gauges along with duplicates are used for further processing (e.g., calibration of process model or measuring a printed pattern) the redundant data may cause degraded performance (e.g., bad model fit, wasted measurement time and effort, etc.).

In an embodiment, a further selection of a sub-set of gauges may be performed based on the merged subset 516 with no duplicate gauges. For example, at step 522, a selection of a sub-set of gauges based on a sequence of gauges may be performed again. Such sequence of gauges refers to a ranking or an order of gauges within the merged subset 516. In an embodiment, the sub-set may be selected from the merged subset 516 based on one or more properties such as gauge name, or other properties e.g., dose, focus, weight, etc.

If the merged subset of gauges 516 do not include duplicate gauges, at step 518, a selection of subset of gauges based on the sequence of gauge may be performed again, similar to that at step 522.

In the subsequent step 524, the selected sub-set of gauges of the merged subset of gauges 516 with no duplicates will be output. At step 524, the sub-set of gauges may be configured to calibrate the process model. For example, the subset may be configured in a GDS file format or other file formats acceptable during simulation of a patterning process model (e.g., in process of FIG. 2). Then, during the calibration process, appropriate gauge information may be extracted from the selected gauges to determine parameters of the process model. Such calibration process is an iterative process, where values of the parameters are modified till a desired model performance (e.g., defined in terms of CD, EPE, or other performance metric) is achieved.

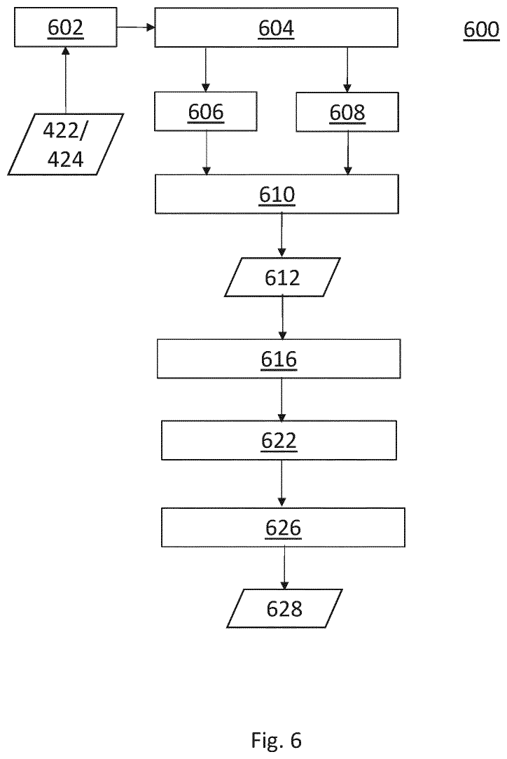

FIG. 6 illustrates a flowchart for a method of a model-based selection of gauges, according to an embodiment. In an embodiment, the method employs different version of models (e.g., process models) based on an optimization algorithm such as a genetic algorithm (GA). A genetic algorithm may be a method for solving both constrained and unconstrained (e.g., on model parameters) optimization problems that is based on natural selection. The genetic algorithm may repeatedly modify a population of individual solutions (e.g., model parameters). The following description describes the method using genetic algorithm as an example, but does not limit the scope to such algorithm. Other appropriate algorithms may be used to generate different version of the model.

The method comprises as an initial step 602, obtaining the set of selected gauges 422/424 (or 426/428) having one or more properties associated with the patterning process, as discussed earlier with respect to FIG. 4. The selected gauges 422/424 (or 426/428) were obtained based on one or more properties of the gauges. Such property-based selection of gauges has already reduced the number of full-set gauges (e.g., in millions) by orders of magnitude to a sub-set of gauges (e.g., having thousands of gauges instead of millions). Thus, the simulations (e.g., process simulation, GA based simulations) using such selected gauges will be faster compared to simulations using a full-set of gauges.

At step 604, it is determine whether tuning data for an optimization algorithm exist or not. In an embodiment, the tuning data refers to model parameters or parameters associated with GA that are determined based on a previously processed substrate data or test patterns. Such tuning data may provide a better initial simulation conditions which typically leads to faster execution of models or convergence of the GA algorithm. Thus, in an embodiment, the turning data may be used during the model-based selection process, at step 606. If the tuning data does not exist, pre-selected initialization conditions (e.g., model parameters or GA parameters) may be used to execute the GA algorithm at step 608.

Further, at step 610, a plurality of models 612 are calibrated based on execution of the GA algorithm. In an embodiment, the plurality of models 612 are process models having certain parameter values determined using the GA algorithm. In an embodiment, the GA algorithm generates 1000 models. In an embodiment, each model is associated with a model error, as discussed earlier. Further, the models 612 when executed using the selected gauges 422/424 generates model errors that may be associate to a particular gauge of 422/424. In an embodiment, the selected gauges 422/424 does not include use-kept gauges as mentioned earlier in FIG. 4.

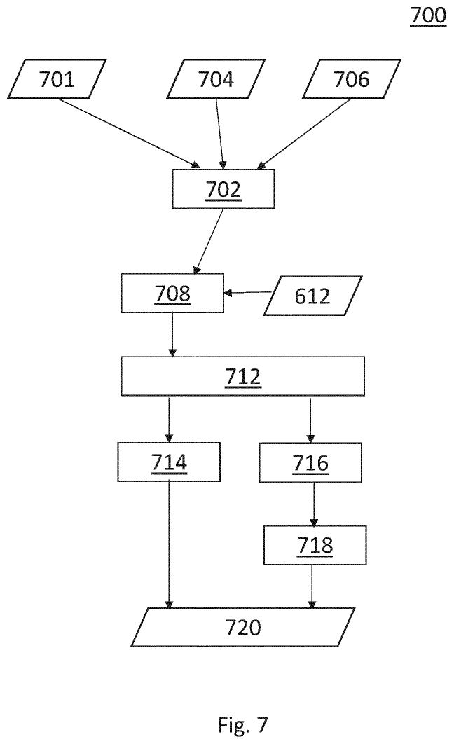

At step 616, a limited number of models may be selected from model 612 to identify diverse models. Diverse models refers to models having parameters are substantially different than a best model (e.g., having least model error) of the plurality of models 612. Choosing diverse model may be advantages to produce different gauge sets, since similar models may produce similar gauges. Such similar gauges may be redundant and may not provide sufficient information to capture wide variations in patterning process. On the other hand, diverse models may capture extreme process conditions, reduce computational time and resources, and faster results may be achieved. In an embodiment, the model selection may be performed as discussed in detail in FIG. 7, discussed later.

At step 622, the selected diverse models 616 are executed with selected gauges 426/428 to determine model error related data. The model error data is then associated with each of the selected gauges. For example, each gauges may be associated with a mean, standard deviation, and/or an error range of the model error.

Further, at step 626, a sub-set of gauges 628 may be selected based the model error data associated. In an embodiment, the diverse model may also be executed to generate additional gauge sets. For example, the set of gauges 628 are selected from the gauges 422/424 based on the mean value of the model error and an error range of the model error. In an embodiment, filtering data such as the mean value and the error range values may be pre-defined values or obtained from a user via a user interface.

Furthermore, the sub-set of gauges 628 may be further appended to include the user-kept gauges as discussed earlier in FIG. 4.

FIG. 7 illustrates a flowchart of an exemplary method of model selection used at step 616 of FIG. 6, according to an embodiment. At step 702, a user may input a number of models 702 to be selected from the plurality of models 612. Further, at step 702, the user may input a threshold ratio 704 (e.g., 0.5) also referred as a threshold value associated with a model error. For example, a ratio may be computed by dividing a first model error value of a given model of the plurality of models 612 by a second model error value of the best model (e.g., having least model error).

In an embodiment, at step 702, calibration data 706 may be provided to determine a best model among the plurality of model 612. For example, the calibration data includes data associated with previously processed substrate of a patterning process. Such data may include CD values, dose, focus, or other process conditions. In an embodiment, the calibration data 706 comprises one or more measurement data on a wafer, a reticle, or a simulated structure.

The plurality of models 612 may be executed using such calibration data 706 to determine model errors. For example, model error is a difference between model result (e.g., CD) and calibration data (e.g., CD). In an embodiment, the model error may be a root mean square value (RMS) computed as mentioned earlier in FIG. 3.

At step 708, a candidate model list may be generated using the threshold ratio 704, and the model error value associated with each of the plurality of models 612. For example, ratio of the model error value of a given model of 612 and the model error of a best model at step 702 is calculated and compared with the threshold ratio 704. In an embodiment, the ratio may be determined with respect model error obtained by execution of a given model with calibration data. If the ratio does not exceeds the threshold ratio (e.g., 1.5) then, the model is considered as a candidate model. In an embodiment, 1000 models may be available and 200 candidate models may be selected by comparing with a specification such as the threshold ratio (e.g., 1.5). However, it may be desired to select a user-defined number (e.g., user input 706) or a pre-determined number of models. For example, out of 200 candidate models, only 5 or 10 diverse models may be desired.

At step 712, a determination of is made whether a number of the candidate model 708 is larger than the pre-determined number (e.g., 706). If the number of the candidate models 708 are more than a pre-determined number, step 716 is executed.

At step 716, a similarity metric of the candidate models 708 is determined. A similarity metric is a measure of how similar a given candidate model is to a best model (e.g., having least RMS value). In an embodiment, the similarity metric may be a cosine similarity metric, which is computed as a cosine of two vectors where each vector may be representative of a given model of the candidate models 708. In an embodiment, a model having relatively low (or high) cosine values indicates the model is a diverse model.

At step 718, a list of diverse models 720 are selected from the candidate models 708 based on the similarity metric. For example, the candidate models are arranged an ascending order of value of the cosine similarity metric. Then, a pre-determined number of models (e.g., user input 706) may be selected from the sorted candidate models. For example, 5 diverse model may be selected from the 200 candidate models.

At the step 714, if number of candidate models is less than the pre-determined number (e.g., user input 706), then the entire candidate model lists may be provided as diverse models 720.

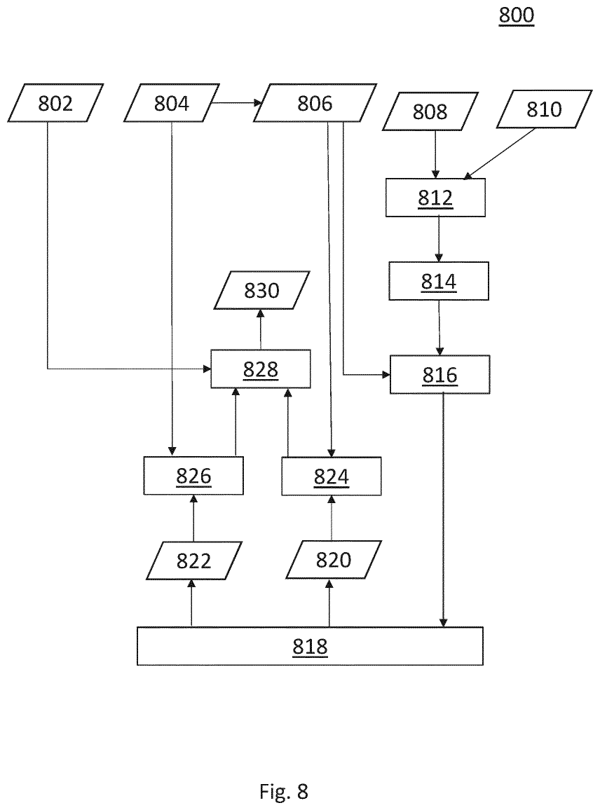

FIG. 8 illustrates an overview of a flowchart of an exemplary method 800 that involves execution of several steps of FIGS. 4, 5, 6, and 7, discussed above, for improving gauge selection based on selected models.

The method 800 receives several inputs including (i) calibration data 808 (similar to that discussed earlier in FIG. 7), (ii) de-noise parameters 806 associated with model error to identify and eliminate outlier data, (iii) an iteration number 804 associated with desired number of gauges to be selected, (iv) merge rules 802 that provides basis for merging different sub-sets gauges that will be obtained during the selection process, and (v) a model lists 810 (e.g., candidate models 708 or diverse models 720 of mentioned FIG. 7).

At step 812, a check job may be generated based on the calibration data 808, the model lists 810 (e.g., 5 diverse models), and full-set of gauges (e.g., 1 million). The check job comprises data (e.g., model errors, CD values, etc.) generated by simulating each model of the model list 810 using the full-set of gauges. For example, the check job comprises data associated with 1 million gauges per model. Further, at step 814, the data in the check job is combined, for example, in a single table.

At step 816, the combined data is cleaned to remove outliers based on the de-noise parameters 806. For example, gauges having small error or relatively large biases may be removed from the combined data of the check job.

At step 818, a dataframe may be generated based on cleaned results of the simulation of the models 810. As mentioned earlier, in an embodiment, dataframe is a representation of data in row and column format. In an embodiment, the dataframe comprises model error data per gauge. This, model error data may be used to compute a mean value of error per gauge, an error range per gauge, or other statistical metric that can be used for statistical analysis. Further, the dataframe may be used to generate an error range histogram 820 and a mean error histogram 822. The histograms are a representation of distribution of numerical data, such as the error range values and the mean error values.

At step 824, a first subset of gauges may be selected from the dataframe based on model error ranges or the error range histogram 820 and a desired number of gauges (e.g., input 804) to be selected. In an embodiment, a second subset of gauges may be selected from the dataframe based on the mean error values or the mean error histogram 822 and a desired number of gauges (e.g., input 804) to be selected. In an embodiment, the selection of the first sub-set may be based on a threshold value of the error range. For example, select gauges having error range greater than 10% and/or select gauges having mean error value greater than 20% with respect to a best model.

At step 828, the first subset of gauges and the second subset of gauges may then be merged based on the merge rule 802. Such merging of the gauges may cause some gauges that do not satisfy the merge rule to be eliminated. In an embodiment, the merge rule comprises rules (e.g., if-conditions) associated with the error range and/or mean model error. For example, a merge rule may be merge gauges that are within 15% of mean error value and/or merge gauges that are within 10% increments of error range values. Further, the result of the step 828 may be output as selected gauges 830.

FIG. 9A illustrates an exemplary method of gauge selection for use in a calibrating a process model associated with a patterning process, according to an embodiment.

In some embodiments, a method 900 includes, at P902, obtaining a set of input gauges 902 having one or more properties associated with the patterning process. The input gauges 902 may be obtained as discussed in step 302/402 of FIGS. 3/4. For example, the input gauges may be full-gauge set, reference gauges, etc. Furthermore, as mentioned earlier, the one or more parameters may include a value of critical dimension of a wafer, a curvature associated with the pattern; and/or an intensity used in the patterning process. The first property parameter may include a model error, and the model error may be a difference between a reference contour and a simulated contour generated from a simulation of a process model of the patterning process. The reference contour may be a measured contour from a scanning electron microscope.

The method 900 includes, at P904, selecting a subset of initial gauges 904 from the set of input gauges 902. For example, the number of the set of input gauges 902 may be one million, after selecting the subset of initial gauges 904 from the set of input gauges 902 based on the one or more properties, the number gauges in the subset of initial gauges 904 may be reduced to 1000 per property. In an embodiment, the selecting the subset of initial gauges 904 from the set of input gauges 902 can be performed as discussed earlier in the step 412 of FIG. 4.

FIG. 9B illustrates an exemplary process of selecting a subset of initial gauges 904 from the set of input gauges 902 for use in a calibrating a process model associated with a patterning process, according to an embodiment.

In some embodiments, a process P904 for selecting a subset of initial gauges 904 from the set of input gauges 902 for use in a measuring process associated with a patterning process can include, at P912, determining a first subset of gauges 912 from the set of input gauges 902 based on a first property parameter of the one or more properties, the first subset of gauges 912 being configured to calibrate a process model. The calibration of the process model used by the first subset of gauges 912 can be performed as discussed earlier in FIGS. 3, 4 and 5. For example, the first set of gauges 912 may include the first property parameter of the one or more properties, and the first set of gauges 912 having the first property parameter may be a model error, and the model error may be used to calibrate the model error of the process model.

The determining of the first subset of gauges 912 from the set of input gauges 902 can be performed as discussed earlier in the step 512 of FIG. 5.

At P912-2, the process involves filtering the set of the input gauges 902 based on user defined gauges to determine the first subset of gauges 912. The filtering of the set of the input gauges 902 can be performed as discussed earlier in the step 412 and 418 of FIG. 4 and further in FIG. 5.

At P914, determining a second subset of gauges 914 from the set of input gauges 902 based on a second property parameter of the one or more properties. The determining of the second subset of gauges 914 from the set of input gauges 902 can be performed as discussed earlier in the step 418 of FIG. 4 and further in FIG. 5.

At P916, merging the first subset of gauges 912 and the second subset of gauges 914 to be a merged subset of gauges 916. The merging the first subset of gauges 912 and the second subset of gauges 914 can be performed as discussed earlier in the step 514 of FIG. 5.

At P918, determining if the merged subset of gauges 916 include duplicate gauges.

At P920, selecting a third subset of gauges 920 from the merged subset of gauges 916 such that the third subset 920 does not include the duplicate gauges, the third subset of gauges 920 being configured to calibrate the process model. The determination of the merged subset of gauges 916 including duplicate gauges can be found in the previous step discussed in step 516 of FIG. 5.

At P922, responsive to the determination that no duplicate gauges exist, selecting the merged subset of gauges 916 to calibrate the process model. The selecting the merged subset of gauges 916 can be performed as discussed earlier in FIG. 5.

FIG. 10A illustrates an exemplary method of generating gauges for a patterning process, according to an embodiment. The method is also referred as model-based selection process in an embodiment, e.g., with reference to FIGS. 6, 7, and 8.

In some embodiments, a method 1000 for generating gauges for a patterning process can include, at P1002, obtaining initial gauges 1002 having one or more properties associated with the patterning process. In an embodiment, the initial gauges 1002 having one or more properties may be obtained as discussed earlier in FIG. 3 and the step 602 of FIG. 6.

As mentioned earlier, the one or more parameters may include a value of critical dimension of a wafer, a curvature associated with the pattern; and/or an intensity used in the patterning process.

At P1004, the method involves calibrating, via an optimization algorithm using the initial gauges 1002, a plurality of models M1004 configured to determine gauges 1008, each model of the plurality of models M1004 being associated with a model error value. The plurality of models M1004 may be an optical model, a resist model, or an etch model, and the models M1004 may be used to generate the one or more properties such as the model error, and the model error may be used for the initial gauges selection. The calibration of the plurality of models M1004 configured to determine gauges 1008 can be performed as discussed earlier in the step 610 of FIG. 6.

As discussed earlier, the model error value may be associated with a model error, the model error being a difference between a reference contour and a simulated contour generated from a simulation of a process model of the patterning process, the reference contour being a measured contour from an image capture device. The model error value may be a root mean square value of the difference between the reference contour and the simulated contour.

The root mean square may be a square root of the arithmetic mean of the squares of the values. For example, the root mean square of the difference between the reference contour and the simulated contour may be the root mean square of arithmetic mean of the squares of the difference between the reference contour and the simulated contour in this invention. In an embodiment, the model error is RMS may be computed as discussed earlier in FIG. 3.

At P1006, determining candidate models M1006 from the plurality of models M1004 based on a comparison of the model error value with respect to a lowest model error value of a particular model in the plurality of models M1004. The candidate models M1006 may be an optical model, a resist model, or an etch model, and the candidate models M1006 may be used to generate the one or more properties such as the model error, and the model error may be used for the initial gauges selection. In an embodiment, the determination of the candidate models M1006 from the plurality of models M1004 can be performed according to the step 708 of FIG. 7.

At P1008, selecting the gauges 1008 for the patterning process based on the candidate models M1006. The selecting of the gauges 1008 may be based on a mean value of the model error; a standard deviation value of the model error; and/or a peak-to-peak value of the model error determined by the candidate models M1003. In an embodiment, the selecting the gauges 1008 for the patterning process can be found earlier in the disclosure with respect to FIG. 6.

FIG. 10B illustrates an exemplary process P1002 of obtaining initial gauges 1002 having one or more properties associated with the patterning process, according to an embodiment. In some embodiments, the process P1002 includes, at P1012, determining a first subset of gauges 1012 from the initial gauges 1002 based on a first property of the one or more properties, the first subset of gauges being configured to calibrate a process model. The calibration of the process model used by the first subset of gauges 1012 may be similar to as discussed with respect to FIG. 5. For example, the first set of gauges 1012 may include the first property parameter of the one or more properties, and the first set of gauges 1012 having the first property parameter may be a model error, and the model error may be used to calibrate the process model. In an embodiment, the determination a first subset of gauges 1012 from the initial gauges 1002 based on a first property of the one or more properties is discussed with respect to FIG. 5.

At P1012-2, filtering the set of initial gauges 1002 by use of user defined gauges 1002-2 to determine the first subset of gauges 1012. The filtering of the set of initial gauges 1002 may be similar to the filtering process discussed earlier in FIGS. 4 and 5.

At P1014, determining a second subset of gauges 1014 from the initial gauges 1002 based on a second property of the one or more properties. The determining of the second subset of gauges 1014 may be similar to as discussed earlier in FIGS. 4 and 5.

At P1014-2, filtering the set of initial gauges 1002 by use of user defined gauges 1002-2 to determine the second subset of gauges 1014. The filtering of the set of initial gauges 1002 may be similar to the filtering process discussed earlier in FIGS. 4 and 5.

At P1016, merging the first subset of gauges 1012 and the second subset of gauges 1014 to be a merged subset of gauges 1016.

At P1018, determining if the merged subset of gauges 1016 include duplicate gauges. In an embodiment, the determination is similar to that discussed in FIG. 5.

At P1020, selecting a third subset of the merged subset of gauges 1020 based on the one or more properties of the patterning process such that the third subset 1020 does not include the duplicate gauges. The selecting of the third subset of the merged subset of gauges 1020 based on the one or more properties is similar to as discussed earlier.

FIG. 10C illustrates an exemplary method of determining a cosine similarity metric between each of the candidate models M1006, according to an embodiment.

In some embodiments, a method P1008 for determining a cosine similarity metric between each of the candidate models M1006 can include, at P1022, determining a cosine similarity metric between each of the candidate models M1006, the cosine similarity metric being a cosine of two vectors, each vector being representative of a given model of the candidate models M1006.

The determination of a cosine similarity metric between each of the candidate models M1006 can be found in the previously discussed step 716 in FIG. 7.

At P1024, selecting, based on the similarity metric, a user-defined number 1024 of diverse models from the candidate models, wherein the diverse model has a value of the similarity metric substantially different from a value of the similarly metric of a model having lest model error value. The selecting of a user-defined number 1024 of diverse models from the candidate models based on the similarity metric can be found in the previously discussed step 718 in FIG. 7.

FIG. 11 illustrates an exemplary of gauge data in a table form (an example of a dataframe). The gauge data comprises one or more properties, e.g., used in the method 900 of gauges selection.

The gauges may be associated with data such as a type (e.g., a pattern types such as 1D or 2D), a property 1 (e.g., a signal of tone), a property 2 (e.g., a based in a x direction), a property 3 (e.g., a base in a y direction), a property 4 (e.g., a head in a x direction), a property 5 (e.g., a head in a y direction), a property 6 (e.g., a critical dimension of a plot), a property 7 (e.g., a critical dimension of a draw), a property 8 (e.g., a critical dimension of a wafer), a property 9 (e.g., a weight), a property 10 (e.g., a name of a pattern), and/or a property 11 (e.g., an intensity used in the patterning process).

FIG. 12 are example representation of the plurality of models (e.g., in method 1000). In an embodiment, each model may be identified by a model number such as 192, 207, 122, etc. As shown, each model of the plurality of models may be associated with a gauge, a model error (e.g., RMS), an error range (e.g., 2D_range), a process parameter 1 (e.g., rat of b0), a process parameter 2 (e.g., rat of b0m), parameter 3 (e.g., rat of b0n), a process parameter 4 (e.g., cA), parameter 5 (cAg1), a process parameter 6 (e.g.cag2), parameter 7 (e.g., cam), a process parameter 8 (e.g., cap), parameter 9 (e.g., cbn), a process parameter 10 (e.g., cbp), parameter 11 (e.g., ccso_2d), a process parameter 12 (e.g., cdetdev), parameter 13 (e.g., cmg1), a process parameter 14 (e.g., cmg2), and/or parameter 15 (e.g., cmgs1_dev). The models in FIG. 12 may be a representation of an optical model, a resist model, or an etch model. According to an embodiment, such models may be used to generate the one or more properties such as the model error, and the model error may be further used for the gauge selection, e.g., as discussed in FIGS. 3, 4, 8.

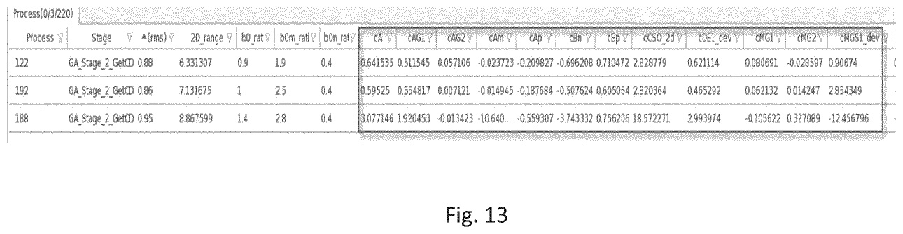

FIG. 13 illustrates an example of similarity of different models. As mentioned earlier, the plurality of models may be associated with a stage, a model error, a range, a process parameter 1 (e.g., rat of b0), a process parameter 2 (e.g., rat of b0m), parameter 3 (e.g., rat of b0n), a process parameter 4 (e.g., cA), parameter 5 (cAg1), a process parameter 6 (e.g., cag2), parameter 7 (e.g., cam), a process parameter 8 (e.g., cap), parameter 9 (e.g., cbn), a process parameter 10 (e.g., cbp), parameter 11 (e.g., ccso_2d), a process parameter 12 (e.g., cdetdev), parameter 13 (e.g., cmg1), a process parameter 14 (e.g., cmg2), and/or parameter 15 (e.g., cmgs1_dev). For example, model 192 can be characterized by or represented in a vector form, e.g., vector1=[0.86, 7.131675, 1, 2.5, 0.4, 0.59525, 0.564817, 0.007121, −0.014945, −0.187684, −0.507624, 0.605064, 2.820364, 0.465292, 0.062132, 0.014247, 2.854349]. Similarly, models 122 and 188 may be represented in vector form. The vectors may be further used to calculate a cosine similarity metric. Further, based on the cosine similarity metric a model may be considered as a diverse model, as discussed earlier in the disclosure. For example, model 192 may be the best model having the lowest RMS among the plurality of models, so it's similarity metric value will be 1. When vectors of model 188 and 192 are used to, the value of their similarity metric is 0.627. Thereby, the model 188 may be a diverse model since the value of it's similarity metric is only 0.627, indicating model 188 is least similar to a best model 192 in these three models. In another example, vectors of models 122 and 188 results in value of similarity metric as 0.92, indicating model 122 is very similar to model 188. Thereby, in model selection process, the model 122 may not be selected as a candidate model.

The gauges selected (e.g., 422/424/426/428) according to the methods of FIG. 3-8 discussed above can be used to improve performance of a patterning process in several ways. For example, as mentioned earlier at step 524, the process model may be calibrated to make better predictions of imaging behavior for variations in the lithographic processing conditions (e.g., scanner properties, resist properties, or etch related properties). For example, calibration uses the selected gauges 422/424 to determine values of parameters (e.g., illumination dose, focus, illumination intensity, pupil shape, etc.) of a process model, such as an optics model or a resist model. For example, parameter values such as dose and focus as it may pertain to an optics model may be provided to a lithographic apparatus of the patterning process so that the imaging performance (e.g., EPE, CD) is improved. For example, the improvement refers to improving the printed pattern of a wafer so that such patterns match closely to the desired pattern. In other words, a difference between the printed pattern and the desired pattern is reduced (e.g., in one embodiment, minimized).

Accordingly, the methods (e.g., 400, 500, 800) discussed above further involve determining a process condition by simulating (e.g., as discussed in FIG. 2) the calibrated process model (e.g., optics model or resist model) using the selected gauges; and exposing, via a lithographic apparatus employing the determined process condition, a substrate. The process condition comprises one or more process parameters, wherein the process parameter is at least one of: dose, focus, or intensity.

In another application, the improvement may be related to a metrology tool. For example, the selected gauges 422/424 in one embodiment correspond to patterns to be measured on a printed substrate. In such embodiment, such selected gauges 422/424 are based on model errors related to variations in the patterning process. Thus, the selected gauges may capture most variations in relatively fewer number (e.g., 10,000; 5,000; 1,000 or less) of measurements of a printed substrate in comparison to a full-gauge set (e.g., having more than 1 million gauges). Hence, when such selected gauges are used, for example, in a sampling plan, the amount of metrology needed will be substantially reduced, thereby improving the throughput of the patterning process.

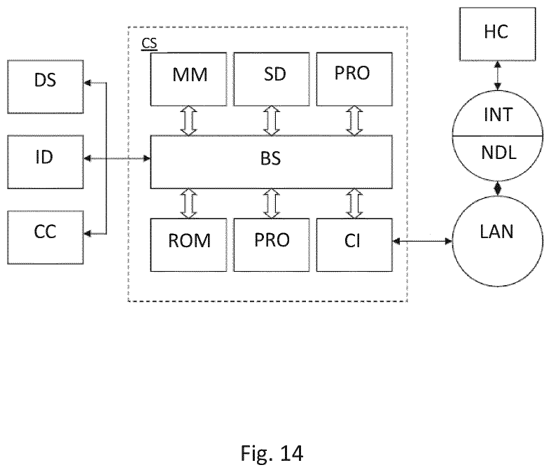

FIG. 14 is a block diagram of an example computer system CS, according to an embodiment.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

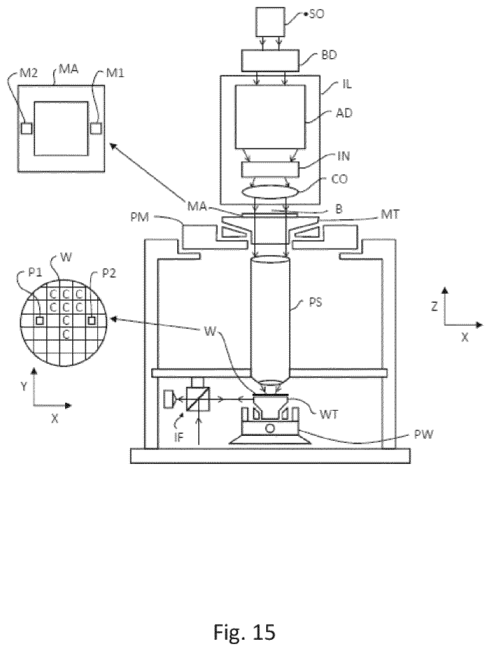

FIG. 15 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. so as to position different target portions C in the path of beam PB. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

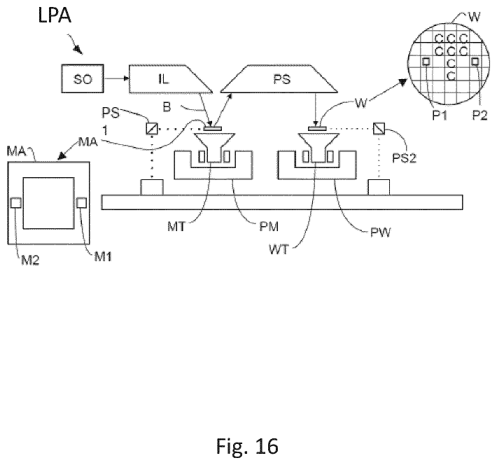

FIG. 16 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-)magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

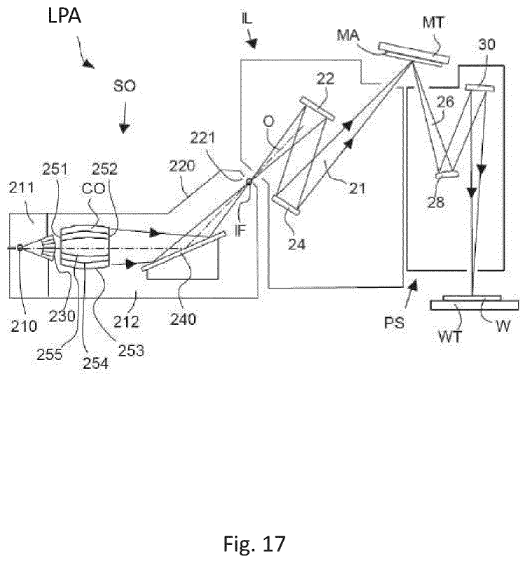

FIG. 17 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

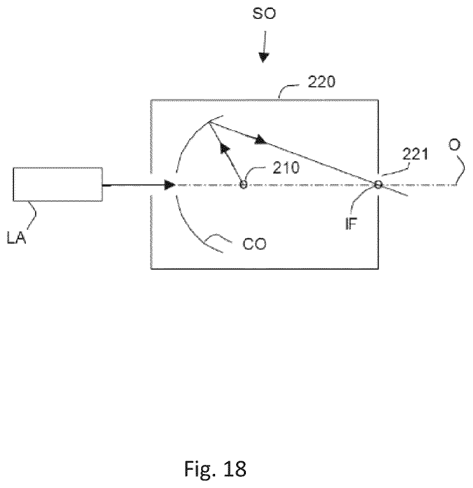

FIG. 18 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

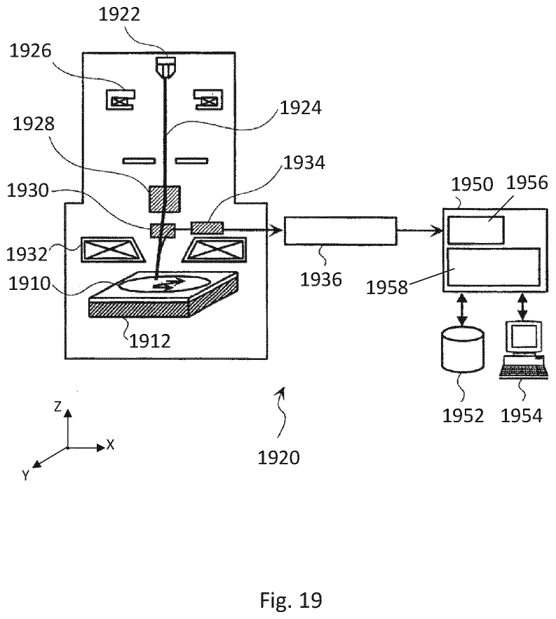

FIG. 19 schematically depicts an embodiment of an electron beam inspection apparatus 1920, according to an embodiment. In an embodiment, the inspection apparatus may be an electron beam inspection apparatus (e.g., the same as or similar to a scanning electron microscope (SEM)) that yields an image of a structure (e.g., some or all the structure of a device, such as an integrated circuit) exposed or transferred on the substrate. A primary electron beam 1924 emitted from an electron source 1922 is converged by condenser lens 1926 and then passes through a beam deflector 1928, an E×B deflector 1930, and an objective lens 1932 to irradiate a substrate 1910 on a substrate table 1912 at a focus.

When the substrate 1910 is irradiated with electron beam 1924, secondary electrons are generated from the substrate 1910. The secondary electrons are deflected by the E x B deflector 1930 and detected by a secondary electron detector 1934. A two-dimensional electron beam image can be obtained by detecting the electrons generated from the sample in synchronization with, e.g., two dimensional scanning of the electron beam by beam deflector 1928 or with repetitive scanning of electron beam 1924 by beam deflector 1928 in an X or Y direction, together with continuous movement of the substrate 1910 by the substrate table 1912 in the other of the X or Y direction. Thus, in an embodiment, the electron beam inspection apparatus has a field of view for the electron beam defined by the angular range into which the electron beam can be provided by the electron beam inspection apparatus (e.g., the angular range through which the deflector 1928 can provide the electron beam 1924). Thus, the spatial extent of the field of the view is the spatial extent to which the angular range of the electron beam can impinge on a surface (wherein the surface can be stationary or can move with respect to the field).

A signal detected by secondary electron detector 1934 is converted to a digital signal by an analog/digital (A/D) converter 1936, and the digital signal is sent to an image processing system 1950. In an embodiment, the image processing system 1950 may have memory 1956 to store all or part of digital images for processing by a processing unit 1958. The processing unit 1958 (e.g., specially designed hardware or a combination of hardware and software or a computer readable medium comprising software) is configured to convert or process the digital images into datasets representative of the digital images. In an embodiment, the processing unit 1958 is configured or programmed to cause execution of a method described herein. Further, image processing system 1950 may have a storage medium 1956 configured to store the digital images and corresponding datasets in a reference database. A display device 1954 may be connected with the image processing system 1950, so that an operator can conduct necessary operation of the equipment with the help of a graphical user interface.

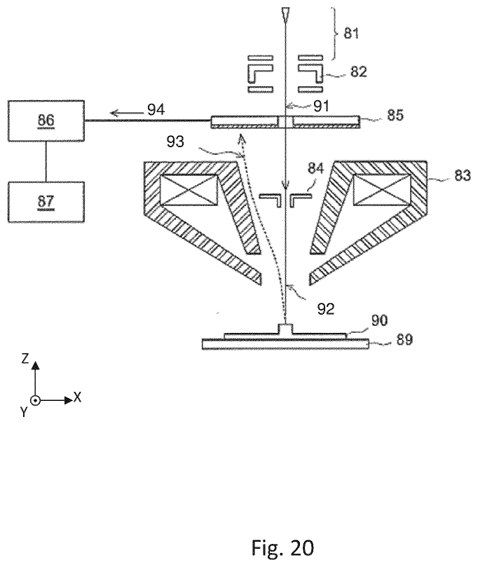

FIG. 20 schematically illustrates a further embodiment of an inspection apparatus, according to an embodiment. The system is used to inspect a sample 90 (such as a substrate) on a sample stage 88 and comprises a charged particle beam generator 81, a condenser lens module 82, a probe forming objective lens module 83, a charged particle beam deflection module 84, a secondary charged particle detector module 85, and an image forming module 86.

The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 88. In an embodiment, the charged particle beam generator 81, the condenser lens module 82 and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly forming at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. So, in an embodiment, the monitoring module 87 is configured or programmed to cause execution of a method described herein. In an embodiment, the monitoring module 87 comprises a computing device. In an embodiment, the monitoring module 87 comprises a computer program to provide functionality herein and encoded on a computer readable medium forming, or disposed within, the monitoring module 87.

In an embodiment, like the electron beam inspection tool of FIG. 19 that uses a probe to inspect a substrate, the electron current in the system of FIG. 20 is significantly larger compared to, e.g., a CD SEM such as depicted in FIG. 19, such that the probe spot is large enough so that the inspection speed can be fast. However, the resolution may not be as high as compared to a CD SEM because of the large probe spot.

The SEM images, from, e.g., the system of FIG. 19 and/or FIG. 20, may be processed to extract contours that describe the edges of objects, representing device structures, in the image. These contours are then typically quantified via metrics, such as CD, at user-defined cut-lines. Thus, typically, the images of device structures are compared and quantified via metrics, such as an edge-to-edge distance (CD) measured on extracted contours or simple pixel differences between images. Alternatively, metrics can include EP gauges as described herein.

Now, besides measuring substrates in a patterning process, it is often desirable to use one or more tools to produce results that, for example, can be used to design, control, monitor, etc. the patterning process. To do this, there may be provided one or more tools used in computationally controlling, designing, etc. one or more aspects of the patterning process, such as the pattern design for a patterning device (including, for example, adding sub-resolution assist features or optical proximity corrections), the illumination for the patterning device, etc. Accordingly, in a system for computationally controlling, designing, etc. a manufacturing process involving patterning, the major manufacturing system components and/or processes can be described by various functional modules. In particular, in an embodiment, one or more mathematical models can be provided that describe one or more steps and/or apparatuses of the patterning process, including typically the pattern transfer step. In an embodiment, a simulation of the patterning process can be performed using one or more mathematical models to simulate how the patterning process forms a patterned substrate using a measured or design pattern provided by a patterning device.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

The embodiments may further be described using the following clauses:
1. A method for gauge selection for use in calibrating a process model associated with a patterning process, the method comprising:
obtaining a set of input gauges having one or more properties associated with the patterning process; selecting a subset of initial gauges from the set of input gauges, the selecting the subset of initial gauges comprises:
determining a first subset of gauges from the set of input gauges based on a first property parameter of the one or more properties, the first subset of gauges being configured to calibrate a process model.
2. The method of clause 1, further comprising filtering the set of the input gauges by use of user defined gauges to determine the first subset of gauges.
3. The method of clause 1, wherein the one or more properties comprises at least one of: a value of critical dimension of a wafer;
a curvature associated with the pattern; and/or
an intensity used in the patterning process.
4. The method of clause 1, wherein the first property parameter includes a model error, the model error being a difference between a reference contour and a simulated contour generated from a simulation of a process model of the patterning process.
5. The method of clause 4, wherein the reference contour is a measured contour from a scanning electron microscope.
6. The method of clause 1, the selecting the subset of initial gauges further comprising: determining a second subset of gauges from the set of input gauges based on a second property parameter of the one or more properties;
merging the first subset of gauges and the second subset of gauges to be a merged subset of gauges; determining if the merged subset of gauges include duplicate gauges; and
selecting a third subset of gauges from the merged subset of gauges such that the third subset does not include the duplicate gauges, the third subset of gauges being configured to calibrate the process model.
7. The method of clause 6, further comprising, responsive to the determination that no duplicate gauges exists, selecting the merged subset of gauges to calibrate the process model.
8. A method for generating gauges for a patterning process, the method comprising: obtaining initial gauges having one or more properties associated with the patterning process; calibrating, via an optimization algorithm using the initial gauges, a plurality of models configured to determine gauges, each model of the plurality of models being associated with a model error value; determining candidate models from the plurality of models based on a comparison of the model error value with respect to a lowest model error value of a particular model in the plurality of models; and selecting the gauges for the patterning process based on the candidate models.
9. The method of clause 8, wherein the obtaining of the initial gauges having one or more properties associated with the patterning process further comprises:
determining a first subset of gauges from the initial gauges based on a first property of the one or more properties, the first property being a weight and/or a model error;
determining a second subset of gauges from the initial gauges based on a second property of the one or more properties;
merging the first subset of gauges and the second subset of gauges to be a merged subset of gauges;
determining if the merged subset of gauges include duplicate gauges; and
selecting a third subset of the merged subset of gauges based on the one or more properties of the patterning process such that the third subset does not include the duplicate gauges.
10. The method of clause 9, further comprising filtering the set of initial gauges by use of user defined gauges to determine the first subset of gauges and the second subset of gauges.
11. The method of clause 9, wherein the one or more model properties further comprise at least one of:
a value of critical dimension of a wafer;
a curvature associated with the pattern; and/or
an intensity used in the patterning process.
12. The method of clause 8, further comprising:
determining a cosine similarity metric between each of the candidate models, the cosine similarity metric being a cosine of two vectors, each vector being representative of a given model of the candidate models.
13. The method of clause 12, further comprising:
selecting, based on the similarity metric, a user-defined number of diverse models from the candidate models, wherein the diverse model has a value of the similarity metric substantially different from a value of the similarly metric of a model having lest model error value.
14. The method of clause 8, wherein the model error value is associated with a model error, the model error being a difference between a reference contour and a simulated contour generated from a simulation of a process model of the patterning process, the reference contour being a measured contour from an image capture device.
15. The method of clause 14, wherein the model error value is a root mean square value of the difference between the reference contour and the simulated contour.
16. The method of clause 8, wherein the selecting the gauges is based on at least one of: a mean value of the model error, a standard deviation value of the model error, and/or a peak-to-peak value of the model error determined by the candidate models.
17. The method of any of clauses 8-16, further comprising:
determining a process condition by simulating the calibrated process model using the selected gauges; and
exposing, via a lithographic apparatus employing the determined process condition, a substrate.
18. The method of clause 17, wherein the process condition comprises one or more process parameters, wherein the process parameter is at least one of: dose, focus, or intensity.
19. A computer program product comprising a non-transitory computer readable medium having instructions recorded thereon, the instructions when executed by a computer implementing the method of any of the above clauses.

1.-15. (canceled)

16. A computer program product comprising a non-transitory computer readable medium having instructions therein, the instructions, when executed by a computer system, configured to cause the computer system to at least:
obtain a set of input gauges having one or more properties associated with a patterning process; and
select a subset of initial gauges from the set of input gauges, the selection of the subset of initial gauges comprising determination of a first subset of gauges from the set of input gauges based on a first property parameter of the one or more properties, the first subset of gauges configured to calibrate a process model associated with the patterning process.

17. The computer program product of claim 16, wherein the instructions are further configured to cause the computer system to filter the set of the input gauges by use of user defined gauges to determine the first subset of gauges.

18. The computer program product of claim 16, wherein the one or more properties comprises one or more selected from: a value of critical dimension of a substrate, a curvature associated with the pattern, and/or an intensity used in the patterning process.

19. The computer program product of claim 16, wherein the first property parameter includes a model error, the model error being a difference between a reference contour and a simulated contour generated from a simulation using a process model of the patterning process.

20. The computer program product of claim 19, wherein the reference contour is a measured contour from a scanning electron microscope.

21. The computer program product of claim 16, wherein the instructions configured to cause the computer system to select the subset of initial gauges are further configured to cause the computer system to:
determine a second subset of gauges from the set of input gauges based on a second property parameter of the one or more properties;
merge the first subset of gauges and the second subset of gauges to be a merged subset of gauges;
determine if the merged subset of gauges include duplicate gauges; and
select a third subset of gauges from the merged subset of gauges such that the third subset of gauges does not include the duplicate gauges, the third subset of gauges configured to calibrate the process model.

22. The computer program product of claim 21, wherein the instructions are further configured to cause the computer system to, responsive to a determination that no duplicate gauges exist, select the merged subset of gauges to calibrate the process model.

23. The computer program product of claim 21, wherein the instructions are further configured to cause the computer system to calibrate the process model using the first subset of gauges.

24. The computer program product of claim 21, wherein the instructions are further configured to cause the computer system to determine a process condition by simulating using the process model and the selected gauges.

25. A computer program product comprising a non-transitory computer readable medium having instructions therein, the instructions, when executed by a computer system, configured to cause the computer system to at least:
obtain initial gauges having one or more properties associated with the patterning process;
calibrate, via an optimization algorithm using the initial gauges, a plurality of models, each model of the plurality of models being associated with a model error value;
determine one or more candidate models from the plurality of models based on a comparison of the model error value associated with each model with respect to a model error value of a particular model in the plurality of models; and
select gauges for the patterning process based on the one or more candidate models.

26. The computer program product of claim 25, wherein the instructions configured to cause the computer system to obtain the initial gauges are further configured to cause the computer system to:
determine a first subset of gauges from the initial gauges based on a first property of the one or more properties, the first property being a weight and/or a model error;
determine a second subset of gauges from the initial gauges based on a second property of the one or more properties;
merge the first subset of gauges and the second subset of gauges to be a merged subset of gauges;
determine if the merged subset of gauges include duplicate gauges; and
selecting a third subset of the merged subset of gauges based on the one or more properties of the patterning process such that the third subset does not include the duplicate gauges.

27. The computer program product of claim 26, wherein the instructions are further configured to cause the computer system to filter the set of initial gauges by use of user defined gauges to determine the first subset of gauges and the second subset of gauges.

28. The computer program product of claim 25, wherein the instructions are further configured to cause the computer system to determine a similarity metric between at least two candidate models.

29. The computer program product of claim 28, wherein the similarity metric is a cosine similarity metric being a cosine of two vectors, each vector being representative of a given candidate model of the candidate models.

30. The computer program product of claim 28, wherein the instructions are further configured to cause the computer system to select, based on the similarity metric, a diverse candidate model from the candidate models, wherein the diverse candidate model has a value of the similarity metric substantially different from a value of the similarity metric of a candidate model having least model error value.

31. The computer program product of claim 25, wherein the one or more properties comprise at least one selected from: a value of critical dimension of a substrate, a curvature associated with the pattern, and/or an intensity used in the patterning process.

32. The computer program product of claim 25, wherein the model error value associated with each model corresponds to a difference between a reference contour and a simulated contour generated from a simulation using a process model of the patterning process, the reference contour being a measured contour from an image capture device.

33. The computer program product of claim 25, wherein the selection of the gauges is based on at least one selected from: a mean value of the model error, a standard deviation value of the model error, and/or a peak-to-peak value of the model error determined by the candidate models.

34. The computer program product of claim 25, wherein the instructions are further configured to cause the computer system to determine a process condition by simulating using a process model and the selected gauges.

35. A method comprising:
obtaining a set of input gauges having one or more properties associated with a patterning process; and
selecting, by a hardware computer, a subset of initial gauges from the set of input gauges, the selection of the subset of initial gauges comprising determination of a first subset of gauges from the set of input gauges based on a first property parameter of the one or more properties, the first subset of gauges configured to calibrate a process model associated with the patterning process.
